(19) United States
(12) Patent Application Publication
(10) Pub. No.: US 2025/0076435 A1
(43) Pub. Date: Mar. 6, 2025

(54) Creating Measurement Data Using Magnetic Resonance

(71) Applicant: Siemens Healthineers AG, Forchheim (DE)

(72) Inventor: David Grodzki, Erlangen (DE)

(73) Assignee: Siemens Healthineers AG, Forchheim (DE)

(21) Appl. No.: 18/814,846

(22) Filed: Aug. 26, 2024

(30) Foreign Application Priority Data
Aug. 28, 2023 (DE) 10 2023 208 213.6

(51) Int. Cl. G01R 33/54; G01R 33/48; G01R 33/561

(52) U.S. Cl. CPC G01R 33/543; G01R 33/4818; G01R 33/561

(57) ABSTRACT

A method for creating measurement data of an object for examination located in a measurement volume of a magnetic resonance system, including: a) increasing a gradient until it has reached a first strength in an encoding direction; b) irradiating an RF excitation pulse while the gradient has the first strength; c) after the end of the RF excitation pulse, reducing the strength of the gradient; d) increasing the gradient again until it has reached a desired strength in the encoding direction; and e) recording MR signals generated by the RF excitation pulse as measurement data along a k-space trajectory specified by the gradient present during the recording and storing this measurement data in a measurement data set, the gradient having the desired strength during the recording of the measurement data.

### TECHNICAL FIELD

The disclosure relates to a method for creating measurement data of an object for examination located in a measurement volume of a magnetic resonance system, in particular with adjustable ultra-short echo times.

### BACKGROUND

Magnetic resonance technology (hereinafter the abbreviation MR stands for Magnetic Resonance) is a known technology with which images of the interior of an object for examination can be generated. To put it simply, in principle, the object for examination is positioned in a magnetic resonance device in a comparatively strong static, homogeneous basic magnetic field, also referred to as a B₀ field, with field strengths of 0.2 tesla to 7 tesla and more, so that its nuclear spins are oriented along the basic magnetic field. To trigger nuclear magnetic resonances that can be measured as signals, radio-frequency excitation pulses (RF pulses) are irradiated into the object for examination, the triggered nuclear magnetic resonances are measured as so-called k-space data, and MR images are reconstructed, or spectroscopy data are determined on this basis. For the local encoding of the measurement data, fast-acting magnetic gradient fields, referred to as gradients for short, are usually superimposed on the basic magnetic field. A scheme used, which describes a temporal sequence of RF pulses to be irradiated and gradients to be switched, is referred to as a pulse sequence (scheme), or sequence for short. The recorded measurement data is digitized and stored as complex numerical values in a k-space matrix. An associated MR image can be reconstructed from the k-space matrix preset with values, for example, by means of a multidimensional Fourier transform.

It is not possible to represent substances or tissues by means of conventional sequences such as, for example, a (T) SE sequence (“(Turbo) Spin Echo”) or a GRE sequence (“Gradient Echo”) as their T2* time, the effective decay of the transverse magnetization of this substance or tissue, is significantly shorter than the shortest possible echo times in the context of these sequences, as a result of which a corresponding signal from these substances or tissues has already decayed at the time of recording.

However, MR methods are already known that allow very short echo times TE (for example TE<500 μs), which are in the range of the corresponding decay time. With these, it is possible, for example, to display bones, teeth, or ice in an MR image, although the T2* time of these objects is in a range of 30-80 μs.

These MR methods include, for example, the UTE sequence (“Ultrashort Echo Time”), as described inter alia in the article by Sonia Nielles-Vallespin “3D radial projection technique with ultrashort echo times for sodium MRI: Clinical applications in human brain and skeletal muscle”, Magn. Res. Med. 2007; 57; p. 74-81. In this type of sequence, after a waiting time following a non-selective or slice-selective excitation, the gradients are increased, and data acquisition is started at the same time. The k-space trajectory is scanned in this way after an excitation runs radially outwards from the k-space center. Therefore, before reconstructing the image data from the raw data recorded in the k-space, this raw data must first be converted to a Cartesian k-space grid by means of Fourier transform, for example, by regridding.

Other MR methods that allow particularly short echo times are zTE (“zero echo time”) and PETRA (“pointwise encoding time reduction with radial acquisition”) sequences and are, for example, described in the article by Weiger et al., “MRI with Zero Echo Time: Hard versus Sweep Pulse Excitation” Magnetic Resonance in Medicine 66: p. 379-389, 2011, and in U.S. Pat. No. 8,878,533B2 (PETRA). In both methods, measurement data is recorded in k-space along radial spokes whose gradients, switched for local encoding, are already fully increased at the time of excitation of the spins in an object for examination, which saves valuable encoding time. However, this also creates an area in the center of the k-space, which cannot be scanned by these radial spokes.

An example of a part of a pulse sequence for such a recording of measurement data along radial spokes, as is used in zTE and PETRA methods, is shown in FIG. 2. The top line “Tx/Rx” shows the irradiated RF excitation pulses RF and the readout time windows ADC during which the recording of the measurement data takes place. The middle line “G” shows the gradients switched in an encoding direction, which have reached their desired strength for the subsequent recording of measurement data at the time of irradiation of an RF excitation pulse. The bottom line “k-sp” shows the corresponding k-space points scanned along the k-space trajectory specified by the applied gradient field for recording the measurement data. Here, measured k-space points are shown as black dots, and k-space points, which are before the start of the readout time window and are therefore not read out, are shown as “blank” dots. The fact that k-space points are not read out is due to the fact that, as described, a constant gradient field is already applied before the RF excitation pulse RF is irradiated. As a result, the central k-space point (k=0) would have to be measured at the same time as the RF excitation pulse RF, which is not technically possible. Only after a minimum required switching time Ts after the end of the RF excitation pulse RF, depending on the hardware of the magnetic resonance system used, can the recording of the measurement data be started in the readout time window ADC, which continues to result in a (shortest) echo time TE′. The first k-space point k₀ read out in the readout time window ADC is at a minimum distance from k-space center among the k-space points read out. The last k-space point kₘₐₓ read out in the readout time window ADC is at a maximum distance from k-space center among the k-space points read out. The duration of the readout time window (acquisition period) is determined by the strength of the adjacent gradient field G and the required resolution or the desired field of view (FOV) or matrix of the image to be created from the measurement data.

An associated scanning scheme of the k-space is shown in FIG. 4, a radial k-space spoke corresponding to the measurement data recorded in a readout time window ADC. Measurement data is recorded along radial spokes in different encoding directions until, for example, a desired scanning density in k-space is achieved. The radius of the central area B, in which no measurement data is recorded along the radial spokes described, depends on the echo time TE′, in which the gradient is switched on with constant strength, and thus on the k-space moment accumulated after excitation until the measurement data is recorded.

MR data from this non-radially scanned area B can be recorded on a Cartesian grid in PETRA methods using a single-point MR acquisition method, for example, RASP (“rapid single point”), and reconstructed algebraically from the measurement data of the radial spokes in zTE methods.

In the article by Kobayashi et al., “Gradient-Modulated PETRA MRI,” Tomography, vol. 1, p. 85-90 (2015), a PETRA method is described in which the switched gradients during RF excitation have a lower strength compared to the gradients switched when recording the measurement data in order to reduce a SAR load (“specific absorption rate”) and unwanted susceptibility artifacts. Another PETRA method with artifact correction is described in DE 10 2011 085 033 A1.

Compared to UTE methods, zTE and PETRA methods have the advantage that they are extremely robust and insensitive to magnetic field inhomogeneities and that eddy currents or minimal time shifts of irradiated RF pulses or switched gradients do not have a disturbing influence on the recorded measurement data, which, on the other hand, can be very obstructive in the case of UTE methods.

Compared to UTE methods, RF excitation for zTE and PETRA methods is limited to (as a first approximation) spatially non-selective rectangular pulses (hard pulses). Slice-selective excitation is, therefore, not directly possible with zTE and PETRA methods. These methods are, therefore, always three-dimensional (3D) methods. Unlike UTE methods, excitations or acquisitions limited to two dimensions (2D) are not directly possible. Therefore, UTE methods are more suitable in cases where the measurement time has to be kept short, and the T2* times are comparatively longer-such as, for example, in examinations of the lungs.

Previously known zTE and PETRA methods also do not allow T2* quantification for substances or tissues with decay constants of T2*<500 μs, in which a plurality of recordings with different echo times in the range of 50-500 us has to be acquired in order to determine the desired decay constant. This is because the echo time should always be as short as possible for zTE and PETRA methods. With PETRA methods, it can be extended, but this increases the radius of the central, non-radially scanned area, and the number of Cartesian k-space points to be recorded in this area (and thus the measurement time) increases. Furthermore, the weights of the measurement data in k-space between measurements with different echo times (and thus different radii of the central area) are no longer comparable, so that the desired decay constant cannot be determined directly.

T2* quantifications, in which a plurality of echoes are recorded in one measurement after a common RF excitation, for example, by inversion of the switched gradients, are known, but only with echo times of TE1<100 us and TE2>1.5 ms. However, only substances with T2*>500 us can be quantified in this way.

### SUMMARY

An object of the disclosure is to eliminate the above-mentioned disadvantages and, in particular, to make it possible to record measurement data of an object for examination with different echo times of less than 500 us in a short time, from which decay constants of less than 500 us can be determined.

The object is achieved by a method for creating measurement data of an object for examination located in a measurement volume of a magnetic resonance system as claimed in claim 1, a magnetic resonance system as claimed in claim 14, a computer program as claimed in claim 15, and an electronically readable data carrier as claimed in claim 16.

A method according to the disclosure for creating measurement data of an object for examination located in a measurement volume of a magnetic resonance system comprises the steps:
a) increasing a gradient until it has reached a first strength in an encoding direction,
b) irradiating an RF excitation pulse (RF) while the gradient has the first strength,
c) after the end of the RF excitation pulse, reducing the strength of the gradient,
d) increasing the gradient again until it has reached a desired strength in the encoding direction,
e) recording MR signals generated by the RF excitation pulse (RF) as measurement data along a k-space trajectory specified by the gradient present during the recording and storing this measurement data in a measurement data set, the gradient having the desired strength during the recording of the measurement data.

By reducing the strength of the gradients according to the disclosure, a k-space moment accumulated between the excitation of the MR signals and the recording of the measurement data can be reduced, and/or an echo time that elapses from the excitation to the recording of the measurement data can be artificially extended compared to measurements without such a reduction. It is, therefore, possible to set different echo times TE, in particular in the ultra-short range (<500 μs), with which measurement data of an object for examination is recorded, which items are comparable with each other despite the different echo times and are sufficiently similar to be easily processed with one another. Such measurement data with different but very short echo times (less than 500 μs) can be used to determine decay constants that are themselves shorter than 500 μs.

A magnetic resonance system, according to the disclosure, comprises a magnetic unit, a gradient unit, a radio frequency unit, and a control facility designed to carry out a method according to the disclosure with a gradient reduction unit.

A computer program, according to the disclosure, implements a method according to the disclosure on a control facility when it is executed on the control facility. For example, the computer program comprises commands which, when the program is executed by a control facility, for example, a control facility of a magnetic resonance system, cause this control facility to execute a method according to the disclosure. The control facility can be designed in the form of a computer.

The computer program can also be in the form of a computer program product, which can be loaded directly into a memory of a control facility, with program code means for executing a method according to the disclosure when the computer program product is executed in a computing unit of the computing system.

A computer-readable storage program, according to the disclosure, comprises commands which, when executed by a control facility, for example, a control facility of a magnetic resonance system, cause it to execute a method according to the disclosure.

The computer-readable storage medium can be designed as an electronically readable data carrier comprising electronically readable control information stored thereon, which comprises at least one computer program according to the disclosure and is designed in such a way that, when the data carrier is used in a control facility of a magnetic resonance system, it executes a method according to the disclosure.

The advantages and aspects specified with regard to the method also apply analogously to the magnetic resonance system, the computer program product, and the electronically readable data carrier.

### BRIEF DESCRIPTION OF THE DRAWINGS

Further advantages and details of the present disclosure will emerge from the exemplary aspects described hereinafter and with reference to the drawings. The examples listed do not constitute a restriction of the disclosure. In the drawings:

FIG. 1 shows a schematic flow chart of a method according to the disclosure,

FIGS. 2 and 3 show schematically illustrated parts of pulse sequence schemes for recording measurement data,

FIG. 4 shows a schematically illustrated exemplary k-space scanning scheme,

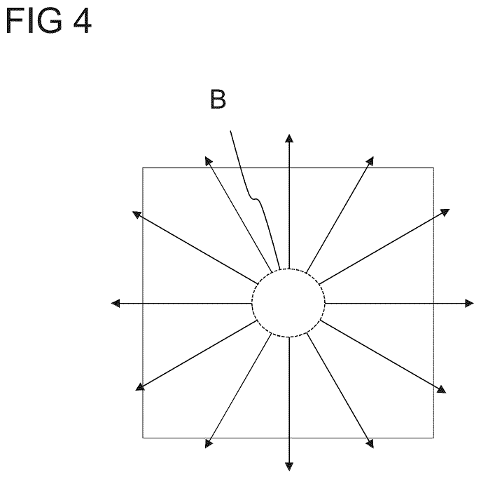

FIG. 5 shows a schematically illustrated magnetic resonance system according to the disclosure.

### DETAILED DESCRIPTION

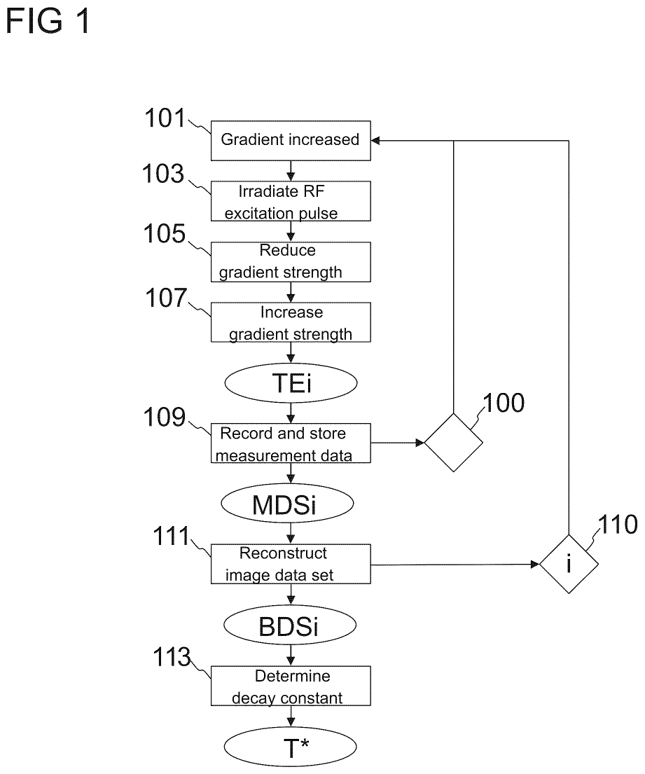

FIG. 1 is a schematic flow chart of a method according to the disclosure for creating measurement data of an object for examination located in a measurement volume of a magnetic resonance system.

In this case, a gradient is increased until it has reached a first strength G1 in an encoding direction (block 101).

While the gradient has the first strength G1, an RF excitation pulse is irradiated into the measurement volume of the magnetic resonance system (block 103).

After the end of the RF excitation pulse, the strength of the gradient increased in block 101 is reduced again (block 105).

The gradient, whose strength was reduced in block 105, is increased again until it has reached a desired strength G2 in the encoding direction (block 107).

After an echo time TEi following the RF excitation pulse, MR signals generated by the RF excitation pulse are recorded as measurement data and stored in a measurement data set MDSi, the gradient having the desired strength G2 during the recording of the measurement data (block 109). The echo time TEi can be so short that MR signals in free induction decay (FID) are recorded as measurement data. In particular, the echo time TEi has a duration of less than 500 μs. The measurement data is recorded along a k-space trajectory predetermined by the gradient applied during the recording, which, in this case, has the form of a radial spoke.

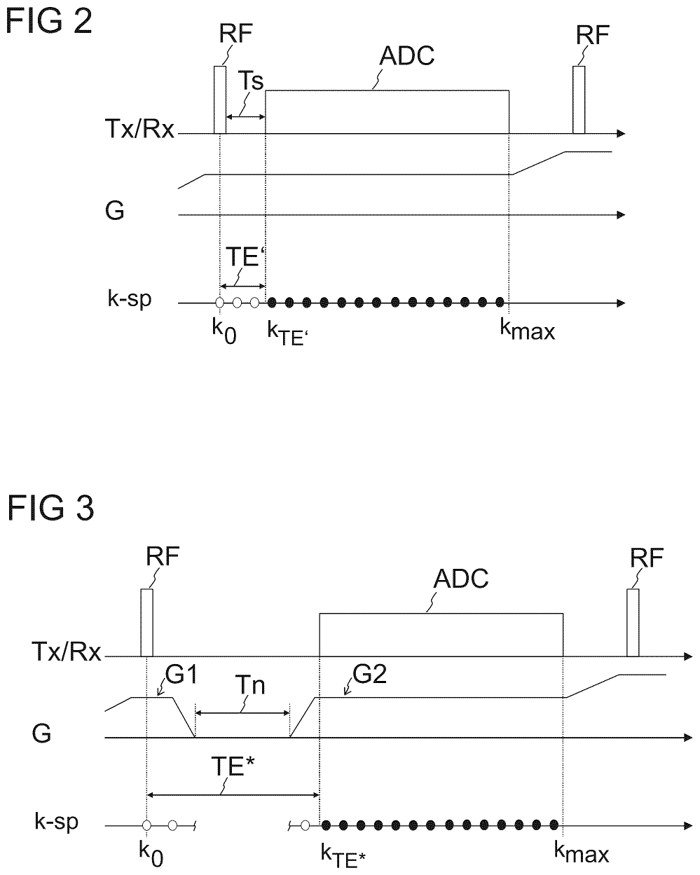

In this case, it is possible to proceed, for example, as shown schematically in FIG. 3 using the example of a part of a pulse sequence. Analogously to FIG. 2, similar parts are provided with the same reference characters. In contrast to FIG. 2, in FIG. 3 the gradient switched in the encoding direction is reduced again from a first strength G1, which is applied during the irradiation of an RF excitation pulse RF, after the end of the RF excitation pulse RF, before the gradient is increased again to a desired strength G2, which it has reached at the latest at the beginning of the recording of the measurement data in the readout time window ADC.

The strength G1 of the gradient can be reduced to the value zero before it is increased again. In this way, it can be achieved that, as long as the strength of the gradient has the value zero, no further k-space moment is accumulated by the gradient in the encoding direction.

The strength of the gradient can have the value zero for a period of time Tn before it is increased again. The desired echo time TE*, which elapses after the RF excitation pulse RF until the start of the readout time window ADC, can be easily controlled by selecting the appropriate period of time Tn.

The strength of the gradient can generally be reduced in such a way that a k-space moment accumulated in the readout time window ADC after the RF excitation pulse RF until the start of recording of the measurement data corresponds to a desired k-space moment. A central area B, in which no measurement data is recorded along the described radial spokes as k-space trajectories, is the same for different repetitions with different reduction i but with the same k-space moment accumulated between RF excitation pulse and the start of recording of the measurement data. Measurement data from different measurement data sets MDSi with different reductions i, but the same k-space moment accumulated between the RF excitation pulse RF and the start of recording of the measurement data is therefore comparable and compatible with one another and can therefore be easily processed with one another. For example, the rate at which the strength of the gradient falls during the reduction and/or the rate at which the gradient rises during the restart and/or a duration for which the gradient still has the first strength G1 after the RF excitation pulse RF until it is reduced, and/or a duration for which the gradient has already reached the desired strength G2 before the start of the recording of measurement data, i.e., before the start of the readout time window ADC, can be taken into account and set appropriately for the desired k-space moment.

In particular, the strength of the gradient can be reduced in such a way that the desired k-space moment corresponds to the smallest possible k-space moment that can be achieved without reducing the strength of the gradient and with the shortest possible switching time Ts between the end of the RF excitation pulse and the start of the recording of the measurement data, depending on the magnetic resonance system used, as shown in FIG. 2, for example. Measurement data recorded in this way is compatible with measurement data recorded by means of a zTE method or a PETRA method, and items can be easily processed with one another.

In general, the strength of the gradient can also be reduced in such a way that a desired echo time TE* elapses between the irradiation of the RF excitation pulse RF and the start of the recording of the measurement data. Here too, for example, the rate at which the strength of the gradient falls during the reduction and/or the rate at which the gradient rises during the restart and/or a duration for which the gradient still has the first strength G1 after the RF excitation pulse RF until it is reduced, and/or a duration for which the gradient has already reached the desired strength G2 before the start of the recording of measurement data, i.e. before the start of the readout time window ADC, and/or, if available, a period of time Tn, in which the gradient between the RF excitation pulse and the start of the subsequent recording of measurement data has the value zero, can be taken into account in a simple manner and set appropriately for the desired echo time TE*.

The steps of blocks 101 to 109 can be repeated with different encoding directions. A query 100 can check whether measurement data has already been recorded in all desired encoding directions and stored in the measurement data set MDSi, or whether a further repetition with a different encoding direction should take place.

In particular, the steps of blocks 101 to 109 can be repeated with different encoding directions until measurement data with a desired density is recorded in k-space.

The first strength G1 can be equal to the desired strength G2. In this way, effects caused by unwanted slice selection due to the gradient switched during excitation remain the same across all recordings of measurement data, making it easier to process items of image data reconstructed from the measurement data with one another. If the first strength G1 of the gradient switched during the irradiation of the RF excitation pulse corresponds to the desired strength G2 of the gradient switched during the recording of the measurement data, the coding scheme according to the disclosure also largely corresponds (except for the reduction of the strength of the gradient) to a coding scheme used in a PETRA method or a zTE method, whereby the measurement data recorded according to the disclosure can also be compared with measurement data recorded by means of a PETRA method or a zTE method, whereby these items can be processed with one another.

From the measurement data set MDSi of the recorded measurement data, an image data set BDSi can be reconstructed, which represents the object for examination (block 111).

The steps of blocks 101 to 109 can also be repeated at least once with a different reduction i from the first strength G1 of the gradient in the step of block 105. A query 110 can check here whether measurement data with all desired reductions i have already been recorded and stored in the associated measurement data set MDSi, or whether a further repetition with a different reduction i should take place.

In this case, the reduction of the first strength of the gradient can be performed in a repetition (110) such that a k-space moment accumulated after the RF excitation pulse until the start of the recording of the measurement data corresponds to the desired k-space moment, and that an echo time TE′ elapsed between the irradiation of the RF excitation pulse and the start of the recording of the measurement data is different from the echo time TE* elapsed during a previous performance of the steps of blocks 101 to 109 with a different reduction i. In this way, measurement data sets MDSi and associated image data sets BDSi can be obtained with the same desired accumulated k-space moment, but with different echo times TE*, TE′.

In the case of a repetition with a different reduction, the first strength of the gradient cannot be reduced until the measurement data is recorded. Without reducing the strength of the gradient in a repetition, the total recording time can be minimized. Such a repetition with a different reduction in the strength of the gradient can thus correspond to a radial part of a zTE method or a PETRA method.

A decay constant (T*) can be determined based on measurement data of different repetitions with different reduction I (113). For example, a map of a T2* decay constant can be determined from image data sets BDSi reconstructed from measurement data sets MDSi recorded by the method according to the disclosure with different reduction i and thus with different echo times TE′, TE* in a manner known per se.

Different desired echo times TE′, TE* of different repetitions with different reduction i are each smaller than 500 μs. In this way, it is also possible to determine decay constants T*, which are smaller than 500 μs.

The method according to the disclosure thus allows an artificial extension of the encoding time of the k-space points read out by reducing the strength of a gradient applied during an RF excitation pulse after excitation by the RF excitation pulse RF, before the strength of the gradient is increased again until the start of recording of the measurement data again. This extension of the encoding time is the same for all k-space points with the proposed method. With known PETRA methods, an extension of the echo time TE would only result in a longer encoding time for measurement data from k-space points read out in Cartesian form in the central area, whereby different, ultra-short echo times in previous PETRA methods and zTE methods mean that the measurement data recorded with different echo times is not comparable.

However, the T2* times can now be determined from image data reconstructed from measurement data recorded according to the disclosure with different reductions and different echo times, for example, by plotting the signal curves pixel by pixel.

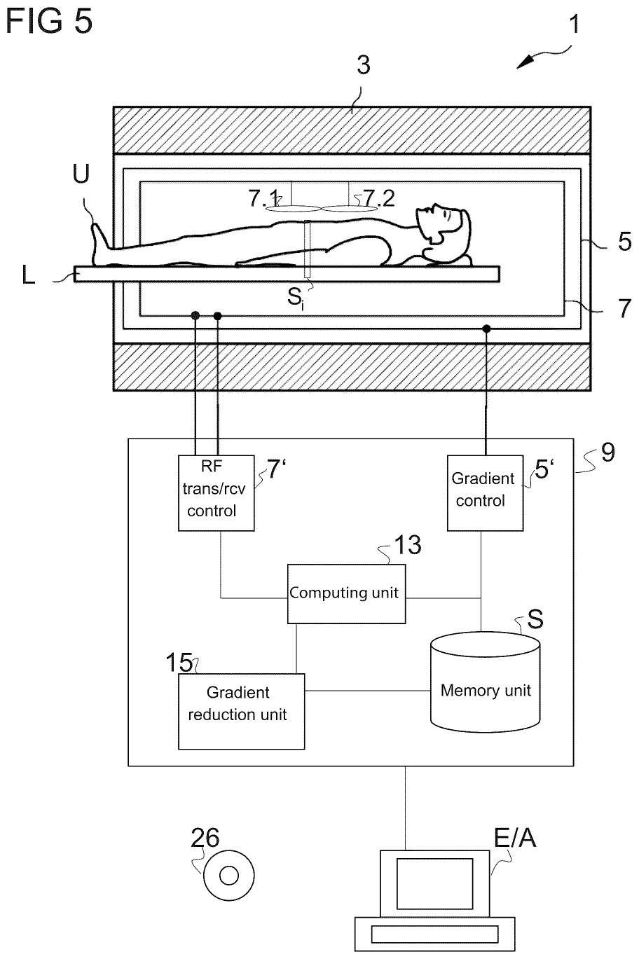

FIG. 5 schematically represents a magnetic resonance system 1 according to the disclosure. This comprises a magnetic unit 3 for generating the basic magnetic field, a gradient unit 5 for generating the gradient fields, a radio frequency unit 7 for emitting and receiving radio-frequency signals, and a control facility 9 designed to carry out a method according to the disclosure.

In FIG. 5, these sub-units of the magnetic resonance system 1 are only shown roughly schematically. In particular, the radio frequency unit 7 can consist of a plurality of sub-units, for example, a plurality of coils such as the schematically shown coils 7.1 and 7.2 or more coils, which can be designed either only for transmitting radio-frequency signals or only for receiving the triggered radio-frequency signals or for both.

To examine an object for examination U, for example, a patient or a phantom, this can be inserted on a couch L into the measurement volume of the magnetic resonance system 1. The slice or slab Sᵢ represents an exemplary target volume of the object for examination, from which echo signals are to be recorded and captured as measurement data.

The control facility 9 is used to control the magnetic resonance system 1 and can, in particular, control the gradient unit 5 by means of a gradient control 5′ and the radio frequency unit 7 by means of a radio frequency transmit/receive control 7′. The radio frequency unit 7 can comprise a plurality of channels on which signals can be transmitted or received.

The radio frequency unit 7, together with its radio frequency transmit/receive control 7′, is responsible for generating and emitting (transmitting) a high-frequency alternating field for the manipulation of the spins in an area to be manipulated (for example, in slices S to be measured) of the object for examination U. The center frequency of the high-frequency alternating field, also referred to as the B1 field, is generally set as close as possible to the resonance frequency of the spins to be manipulated. Deviations of the center frequency from the resonance frequency are referred to as off-resonance. To generate the B1 field, currents controlled by the radio frequency transmit/receive control 7′ are applied to the HF coils in the radio frequency unit 7.

Furthermore, the control facility 9 comprises a gradient reduction unit 15, with which reductions of the first strengths of gradients according to the disclosure and, in particular, the courses of the gradients after irradiation of an RF excitation pulse RF and until the start of a subsequent recording of measurement data can be controlled, which can be implemented by the gradient control 5′. Overall, the control facility 9 is designed to carry out a method according to the disclosure.

A computing unit 13 included in the control facility 9 is designed to carry out all the computing operations required for the necessary measurements and determinations. Intermediate results and findings required for this purpose or determined in the process can be stored in a memory unit S of the control facility 9. The units shown here are not necessarily to be understood as physically separate units but merely represent a subdivision into units of meaning, which can also be realized, for example, in fewer or even in a single physical unit.

Control commands can be forwarded to the magnetic resonance system via an input/output facility E/A of the magnetic resonance system 1, for example, by a user, and/or results of the control facility 9, such as, for example, image data, can be displayed.

A method described herein may also be in the form of a computer program comprising commands that execute the method described on a control facility 9. Similarly, a computer-readable storage program may be present, comprising commands which, when executed by a control facility 9 of a magnetic resonance system 1, cause it to execute the method described.

Independent of the grammatical term usage, individuals with male, female, or other gender identities are included within the term.

1. A method for creating measurement data of an object for examination located in a measurement volume of a magnetic resonance system, the method comprising:
a) increasing a gradient until it has reached a first strength in an encoding direction;
b) irradiating an RF (radio frequency) excitation pulse while the gradient has the first strength;
c) after the end of the RF excitation pulse, reducing the strength of the gradient;
d) increasing the gradient again until it has reached a desired strength in the encoding direction; and
e) recording MR signals generated by the RF excitation pulse as measurement data along a k-space trajectory specified by the gradient present during the recording and storing this measurement data in a measurement data set, wherein the gradient has the desired strength during the recording of the measurement data.

2. The method as claimed in claim 1, wherein the first strength is equal to the desired strength.

3. The method as claimed in claim 1, wherein the steps a) to e) are repeated with different encoding directions.

4. The method as claimed in claim 3, wherein the steps a) to e) are repeated with different encoding directions until measurement data with a desired density has been recorded in the k-space.

5. The method as claimed in claim 1, wherein the strength of the gradient is reduced to zero before it is increased again.

6. The method as claimed in claim 5, wherein the strength of the gradient has a value of zero for a period of time before it is increased again.

7. The method as claimed in claim 1, wherein the strength of the gradient is reduced such that a k-space moment accumulated after the RF excitation pulse up to the start of the recording of the measurement data corresponds to a desired k-space moment.

8. The method as claimed in claim 7, wherein the strength of the gradient is reduced in such a way that the desired k-space moment corresponds to the smallest possible k-space moment which can be achieved without a reduction of the strength of the gradient and with the shortest possible switching time between the end of the RF excitation pulse and the start of the recording of the measurement data.

9. The method as claimed in claim 1, wherein the strength of the gradient is reduced in such a way that a desired echo time TE elapses between the irradiation of the RF excitation pulse and the start of the recording of the measurement data.

10. The method as claimed in claim 1, wherein the steps a) to e) are repeated at least once, and a different reduction of the first strength of the gradient occurs during the repetition.

11. The method as claimed in claim 10, wherein in the case of a repetition, the reduction of the first strength of the gradient occurs such that a k-space moment accumulated after the RF excitation pulse up to the start of the recording of the measurement data corresponds to a desired k-space moment, and an echo time elapsed between the irradiation of the RF excitation pulse and the start of the recording of the measurement data is different from an echo time elapsed in a previous execution of steps a) to e) carried out with a different reduction.

12. The method as claimed in claim 10, wherein in the case of the repetition, the first strength of the gradient is not reduced until the measurement data is recorded.

13. The method as claimed in claim 10, wherein a decay constant is determined based on measurement data of different repetitions.

14. A magnetic resonance system, comprising:
a magnetic unit;
a gradient unit;
a radio frequency unit; and
a control facility having a radio frequency transmit/receive control and a gradient reduction unit, wherein the control facility is operable to carry out a method as claimed in claim 1 on the magnetic resonance system.

15. A non-transitory computer-readable storage medium storing a program that comprises commands which, when executed by a control facility of a magnetic resonance system, cause it to execute the method as claimed in claim 1.
